(19) United States
(12) Patent Application Publication
(10) Pub. No.: US 2007/0111499 A1
(43) Pub. Date: May 17, 2007

(54) Wafer redistribution structure with metallic pillar and method for fabricating the same

(75) Inventor: Jian-Wen Lo, Banciao City (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/474,484

(22) Filed: Jun. 26, 2006

(30) Foreign Application Priority Data
Nov. 15, 2005 (TW) 94140168

(51) Int. Cl. H01L 21/44; H01L 23/48

(52) U.S. Cl. 438/612; 257/734

(57) ABSTRACT

A wafer structure and a method for fabricating the same are provided. The wafer structure comprises a substrate, a redistribution structure, a passivation layer, an under bump metallurgy (UBM) layer and a bump. The substrate has a solder pad. The redistribution structure is formed on the substrate and comprises a copper pillar electrically connected to the solder pad. The passivation layer is formed on the redistribution structure and has an aperture to expose the copper pillar. The UBM layer is formed in the aperture and disposed on the copper pillar. The bump is formed on the UBM layer.

This application claims the benefit of Taiwan application Ser. No. 94140168, filed Nov. 15, 2005, the subject matter of which is incorporated herein by reference.

### BACKGROUND OF THE INVENTION

1. Field of the Invention

The invention relates in general to a wafer structure and a method for fabricating the same, and more particularly to a redistribution structure of a wafer structure and a method for fabricating the same.

2. Description of the Related Art

In response to the requirements with regards to the integration and miniaturization of electronic devices, the packaging technology of integrated circuits (ICs) is headed towards miniaturization and high density. Examples of the packaging technology of high-density integrated circuits including the ball grid array (BGA) technology, the chip-scale package (CSP) technology, the flip chip (F/C) technology, and the multi-chip module (MCM) technology are provided. In terms of a high-density integrated circuit, that is, an integrated circuit having more pins per unit area, the speed of signal transmission will be improved if the length of wiring distribution is shortened. Therefore, the application of the metallic pillar capable of shortening the length of wiring distribution has gradually replaced the application of routing and become a mainstream practice in high-density packaging technology.

The solder pads disposed on the chip being so close to each other that the bumps disposed on the solder pads are likely to be electrically connected to each other, causing the occurrences of unexpected short-circuits. Besides, the solder pads being so close to the sawing line of the wafer that the bumps are likely to be sawn when the wafer is being sawn. Therefore, the current bumping technology changes the disposition of the bumps by redistribution. Under certain circumstances, the redistribution layer has to be crisscrossed with the layout path due to the overall layout of the chip, and the three-layered redistribution structure is thus invented.

However, in the three-layered redistribution structure, some of the contacts directly form bumps above the original position of the solder pads, making the bumps to be positioned too low. Referring to FIG. 1, a cross-sectional view according to a conventional wafer structure having a three-layered redistribution structure is shown. The conventional wafer structure 10 includes a substrate 11, two solder pads 12 and 14, a first passivation layer 20, two first redistribution layers 22 and 24, a second passivation layer 30, two second redistribution layers 32 and 34, a third passivation layer 40, an under bump metallurgy (UBM) layer 42, two bumps 52 and 54. The substrate 11 has several solder pads 12, 14 and the first passivation layer 20 disposed thereon. The first passivation layer 20 has several first apertures to expose the solder pads 12 and 14.

The solder pads 12 and 14 respectively adopt different designs of redistribution layers. The solder pad 14 is extended to the right via the first redistribution layer 24 and the second redistribution layer 34, and forms an under bump metallurgy (UBM) layer 44 and a bump 54 at one end of the second redistribution layer 34. A component is electrically connected to the solder pad 14 by contacting the bump 54, thereby redistributing the electrical contacts of the wafer 10. On the other hand, the bump 52 electrically connected to the solder pad 12 is predetermined to be formed above the original position of the solder pad 12. Similarly, the solder pad 12 is extended upwardly via the first redistribution layer 22 and the second redistribution layer 32, and forms the UBM layer 42 and the bump 52 in the second redistribution layer 32. It is noted that an obvious height drop x1 exists between the bump 52 and the bump 54. That is to say, the design of adopting the three-layered redistribution layer and forming the bump 52 on the solder pad 14 would easily cause the bump 52 to be positioned too low, severely affecting the subsequent packaging process.

Referring to FIG. 2, another cross-sectional view according to the conventional wafer structure having the three-layered redistribution layer is shown. The solder pad 16 is slightly extended to the left via the first redistribution layer 26 and the second redistribution layer 36, and forms an under bump metallurgy (UBM) layer 46 and a bump 56 in the second redistribution layer 36. The contact area between the first redistribution layer 26 and the second redistribution layer 36 is too small, so the two layers are likely to come off the structure, severely damaging the electrical characteristics of the components.

Generally speaking, despite the conventional three-layered redistribution layer resolves the problem of crisscrossed circuits, however, when the bump is formed above the solder pad or the extension distance is too short, the bumps are likely to come off the structure if the bumps are positioned too low. The above two problems severely restrict the application of the conventional three-layered redistribution layer, and yet the problems of crisscrossed circuits still remain unresolved.

### SUMMARY OF THE INVENTION

It is therefore an object of the invention to provide a redistribution structure of a wafer structure and a method of fabricating the same. The design adopts a multi-layered redistribution structure, avoiding the occurrences of short-circuits when the circuits are crisscrossed. The bumps are of the same height, thus avoiding height drop. Furthermore, the redistribution layers of the redistribution structure have good contacts and are not easy to be detached.

The invention achieves the above-identified object by providing a wafer structure including a substrate, a redistribution structure, a third passivation layer, an under bump metallurgy (UBM) layer and a bump. The substrate has a solder pad and a first passivation layer. The first passivation layer has a first aperture to expose the solder pad. The redistribution structure is formed on the substrate. The redistribution structure includes at least one redistribution layer, a metallic pillar and a second passivation layer. The redistribution layer is electrically connected to the solder pad, and has at least one top portion and an indented portion. The metallic pillar fills the indented portion and is protruded from the top portion. The second passivation layer is formed on the first passivation layer and surrounds the metallic pillar. The third passivation layer is formed on the redistribution structure and has a third aperture to expose the metallic pillar. The UBM layer is formed in the third aperture and disposed on the metallic pillar with respect to the indented portion. The bump is formed on the UBM layer.

The invention further achieves the above-identified object by providing a wafer structure. The wafer structure includes a substrate, a redistribution structure, a passivation layer, an under bump metallurgy (UBM) layer and a bump. The substrate has a solder pad. The redistribution structure is formed on the substrate. The redistribution structure includes at least one copper pillar electrically connected to the solder pad. The passivation layer is formed on the redistribution structure and has an aperture to expose the copper pillar. The UBM layer is formed in the aperture and is disposed on the copper pillar. The bump is formed on the UBM layer.

The invention further achieves the above-identified object by providing yet another method of fabricating a wafer structure. The method includes the following steps. (a). Providing the substrate having the solder pad and the first passivation layer, wherein the first passivation layer has a first aperture to expose the solder pad. (b). Forming a redistribution layer on the first passivation layer and the first aperture, wherein the redistribution layer has an indented portion. (c). Forming a metallic pillar to fill the indented portion, wherein the metallic pillar is protruded from the redistribution structure. (d). Forming a second passivation layer on the first passivation layer, wherein the second passivation layer surrounds the metallic pillar. (e). Forming a third passivation layer on the second passivation layer, wherein the third passivation layer has a third aperture to expose the metallic pillar. (f). Forming an under bump metallurgy (UBM) layer in the third aperture and on part of the third passivation layer, wherein the UBM layer is electrically connected to the metallic pillar with respect to the indented portion. (g). Forming a bump on the UBM layer.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a cross-sectional view according to a conventional wafer structure having a three-layered redistribution structure;

FIG. 2 (Prior Art) is another cross-sectional view according to the conventional wafer structure having the three-layered redistribution structure;

FIG. 3 is a cross-sectional view of a wafer structure according to a preferred embodiment of the invention;

FIGS. 4A˜4J are flowcharts of a method of fabricating a wafer structure according to the preferred embodiment of the invention; and

FIG. 5 is a perspective of the redistribution structure of the wafer structure according to FIG. 4J.

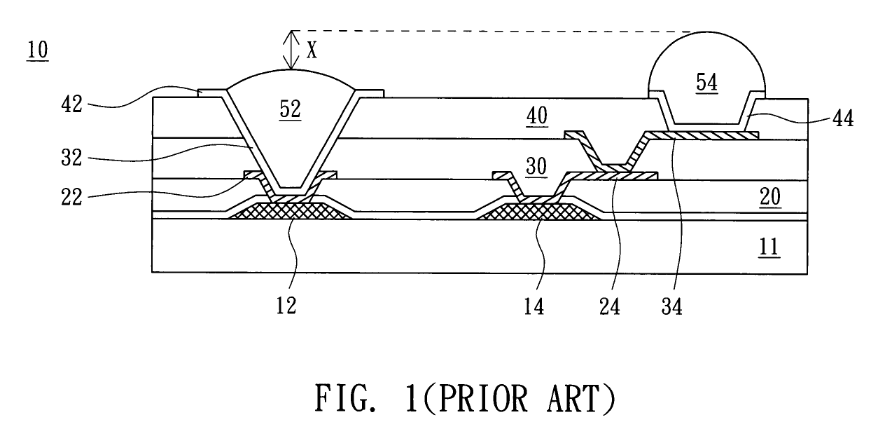

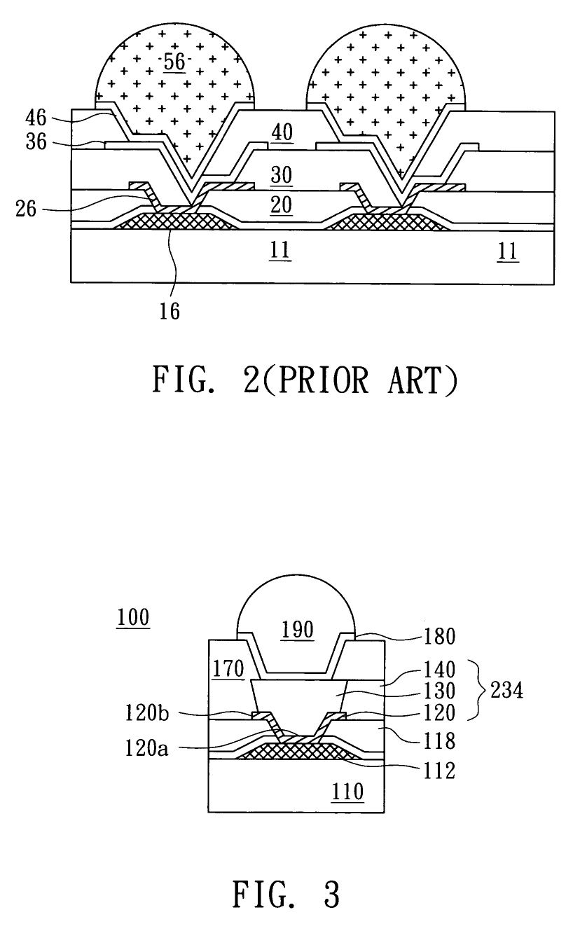

### DETAILED DESCRIPTION OF THE INVENTION

The invention provides a multi-layered redistribution structure and a method for fabricating the same, avoiding the occurrences of short-circuits even when circuits are crisscrossed. According to the invention, the bumps have the same height and are without height drop. At the contact point of the redistribution layer extended from the original position of the solder pad, a metallic pillar is used to fill the indented portion and elevate the under bump metallurgy (UBM) layer, so that the bump extended from the original position of the solder pad has the same height with the bump positioned elsewhere.

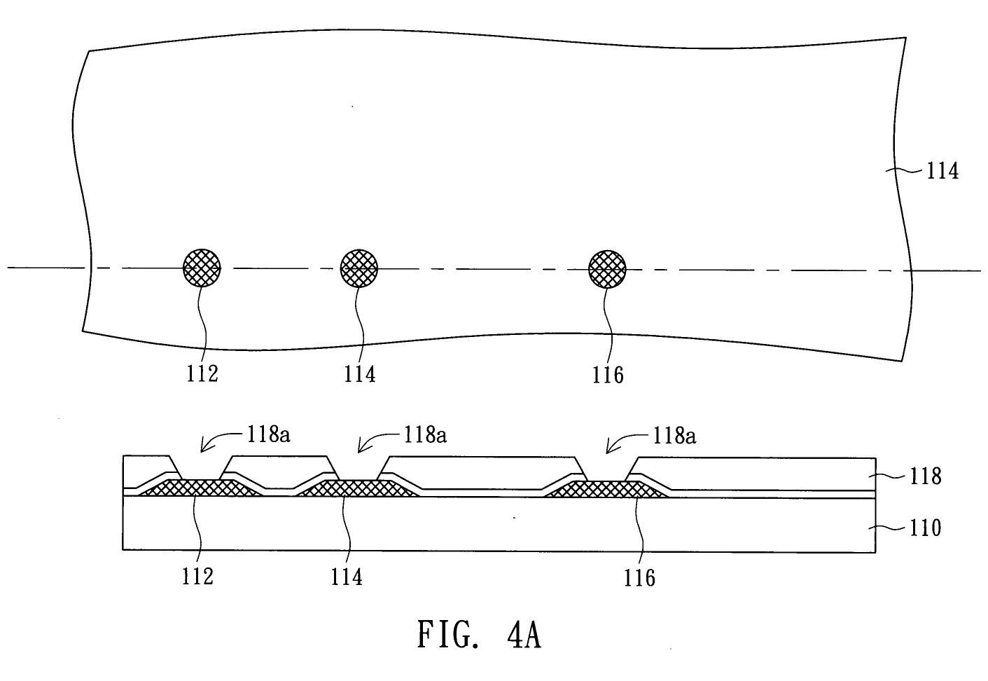

Referring to FIG. 3, a cross-sectional view of a wafer structure according to a preferred embodiment of the invention is shown. The wafer structure 100 of the present embodiment of the invention includes a substrate 110, a redistribution structure 234, a third passivation layer 170, an under bump metallurgy layer (UBM) 180 and a bump 190. The substrate 110 has a solder pad 112 and a first passivation layer 118. The first passivation layer 118 has a first aperture to expose the solder pad 112. The redistribution structure 234 is formed on the substrate 110. The redistribution structure 234 includes at least one redistribution layer 120, a metallic pillar 130 and a second passivation layer 140. The redistribution layer 120 electrically connected to the solder pad 112 has at least one top portion 120b and an indented portion 120a. The metallic pillar 130 fills the indented portion 120a and is protruded from the top portion 120b. The second passivation layer 140 is formed on the first passivation layer 118 and surrounds the metallic pillar 130. The third passivation layer 170 formed on the redistribution structure 234 has a third aperture 170a to expose the metallic pillar 130. The UBM layer 180 formed in the third aperture 170a is disposed on the metallic pillar 130 with respect to the indented portion 120a. The bump 190 is formed on the UBM layer 180.

In other words, the redistribution layer 120 is formed in the first aperture and on the first passivation layer 118. The top portion 120b covers the first passivation layer 118. The indented portion 120a is disposed in the first aperture 118a. Preferably, the metallic pillar 130 is a copper pillar possessing excellent features of conductivity and hardness. The metallic pillar 130, preferably ranging from 5 μm to 8 μm, fills the indented portion 120a of the redistribution layer 120 and is protruded from the top portion 120b of the redistribution layer 120. By doing so, the top surface of the second passivation layer 170 is disposed at the same height with the top surface of the metallic pillar 130, therefore the UBM layer 180 disposed on the metallic pillar 130 is approximately of the same height with the UBM layer 180 disposed on the second passivation layer 170. That is to say, the top surface of the redistribution structure formed above or near the original position of the solder pad has the same height with the top surface of the redistribution structure extended outwardly from the solder pad. Therefore, the UBM layer and the bump formed under the same conditions would have the same height.

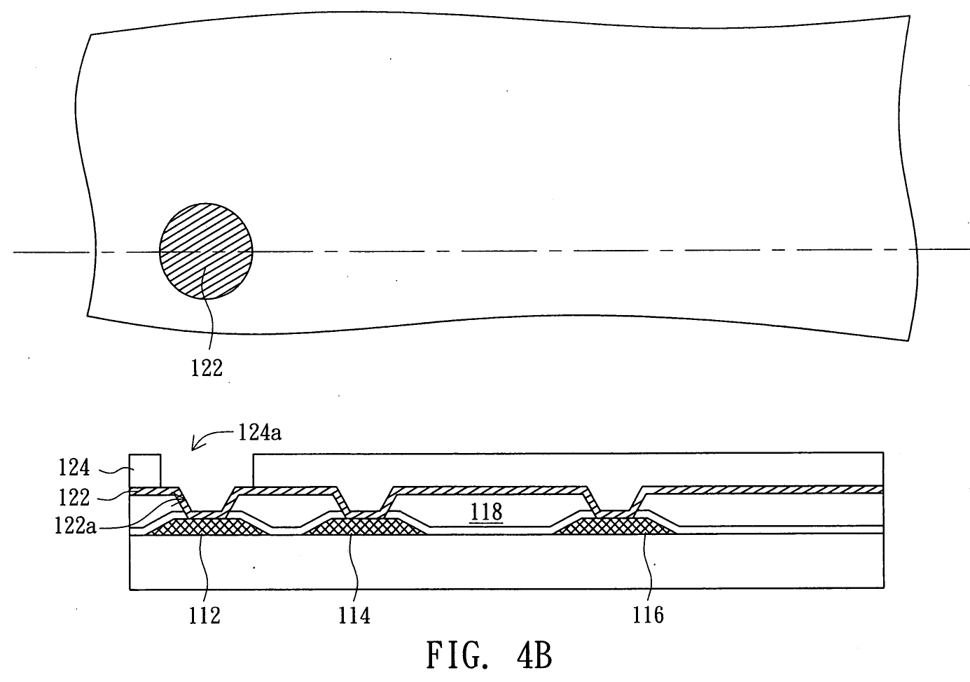

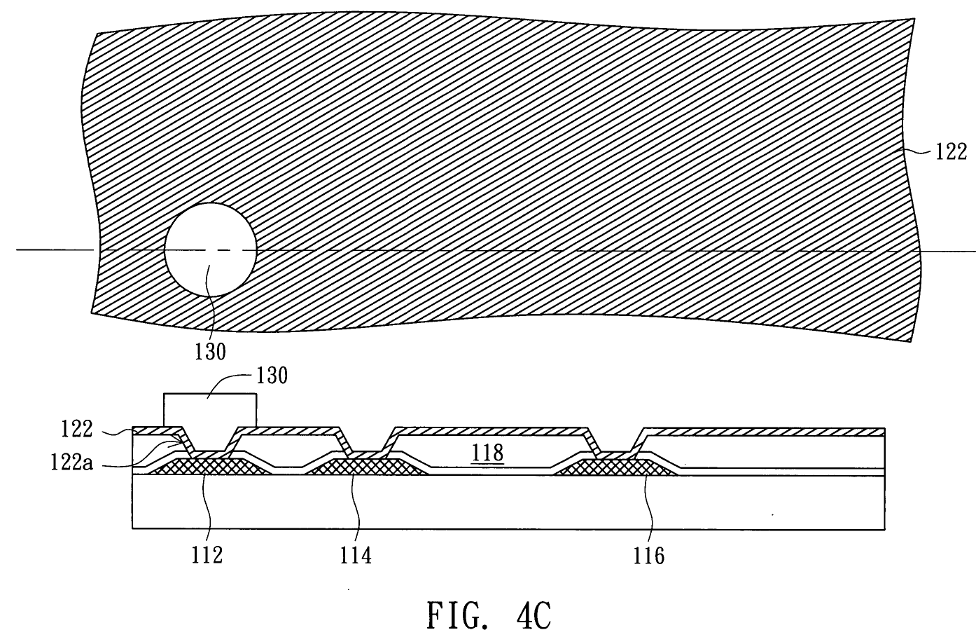

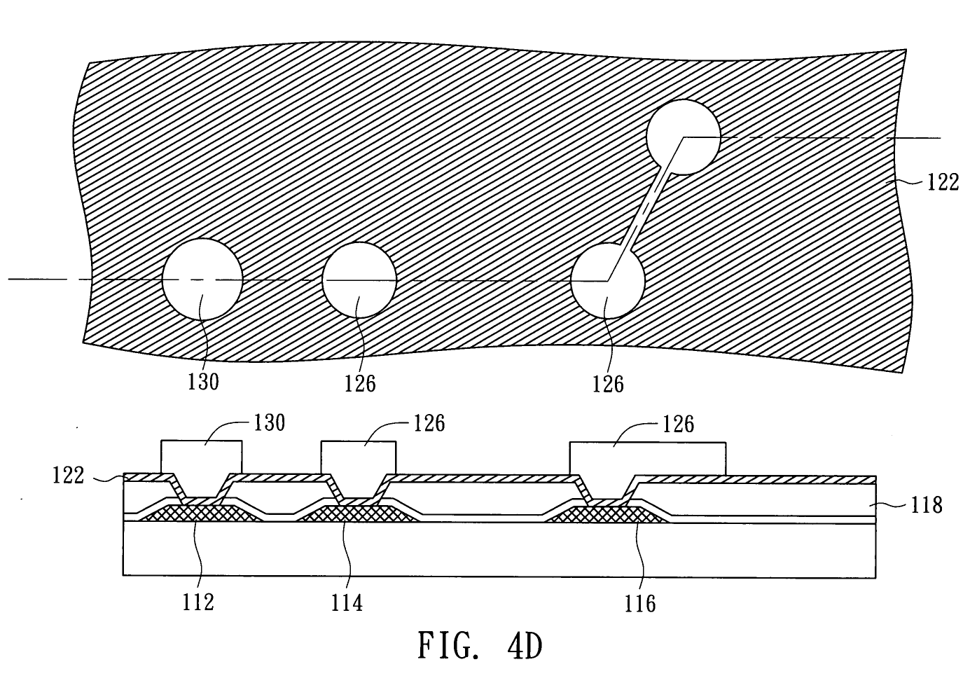

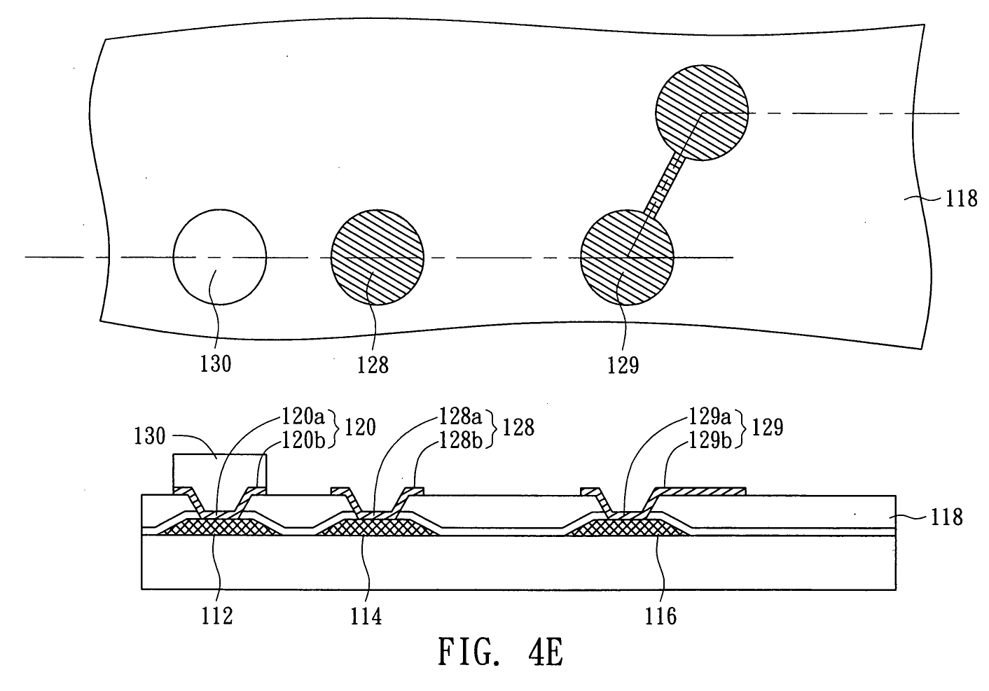

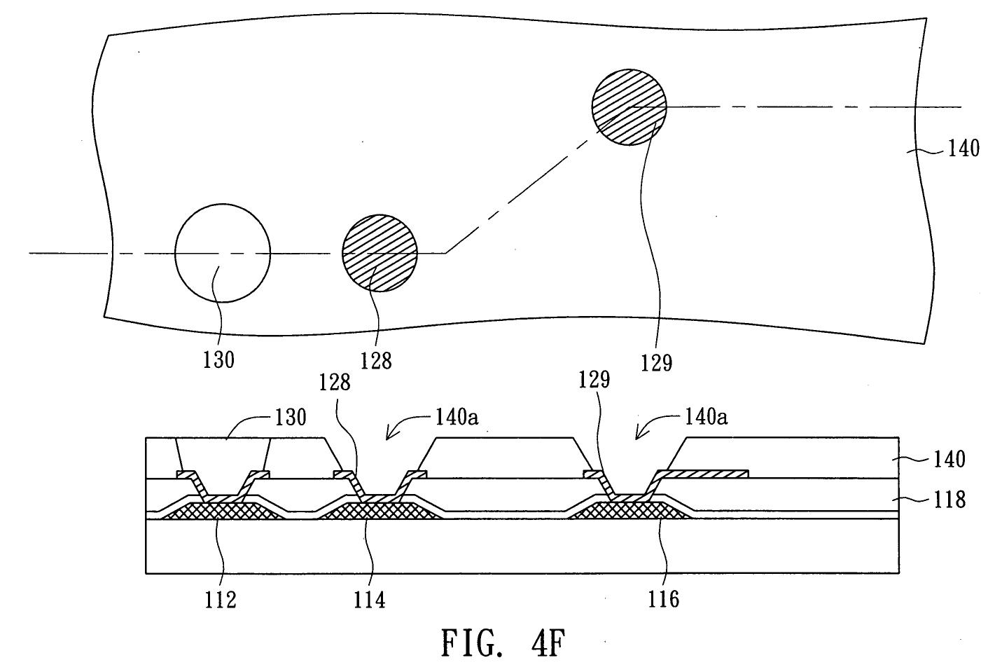

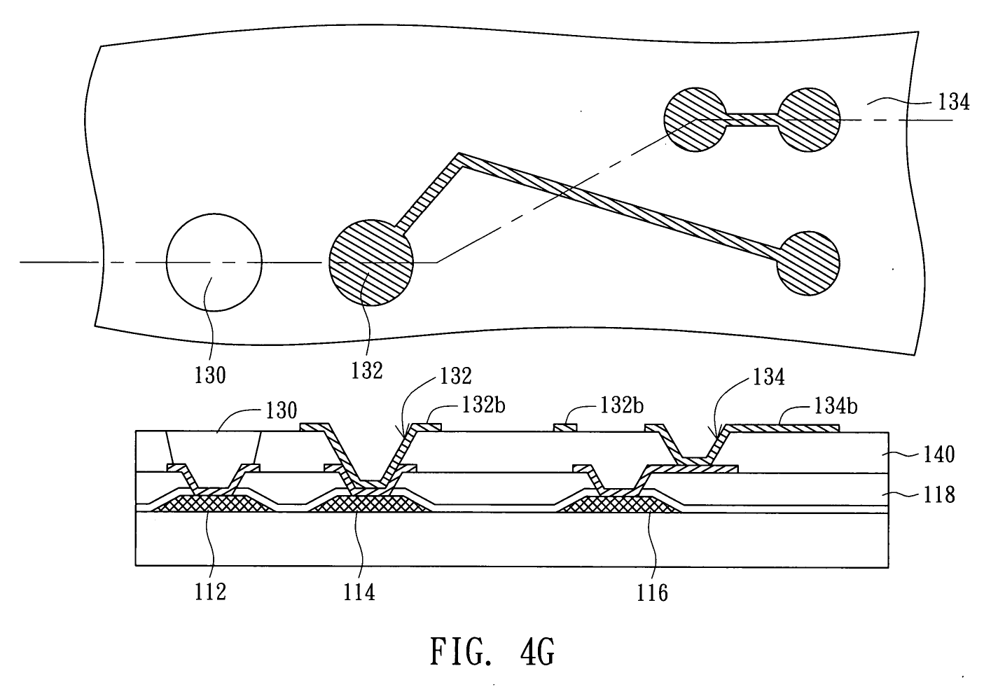

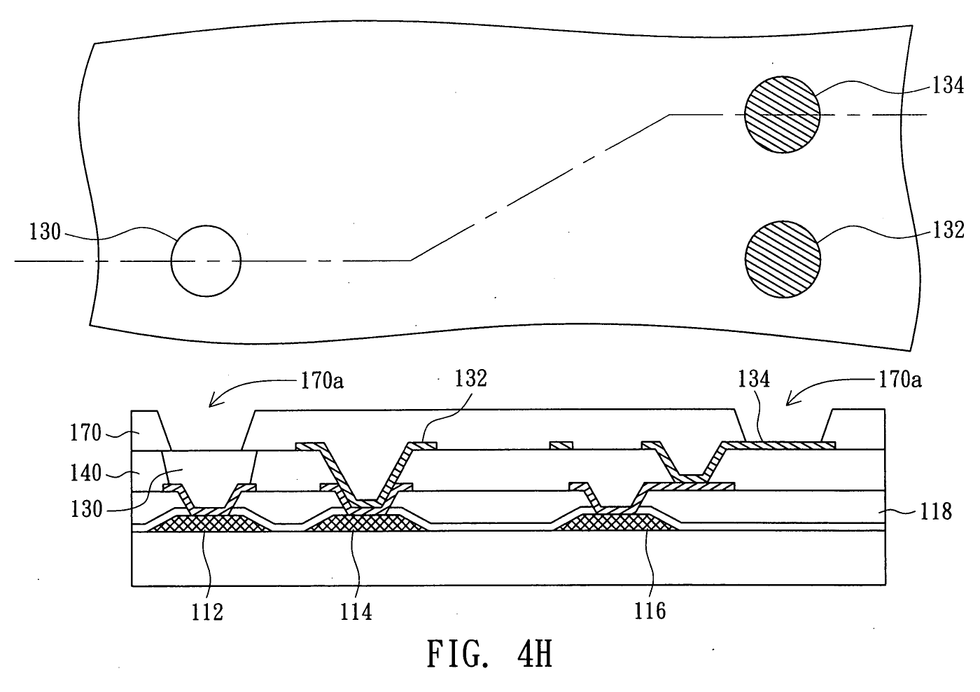

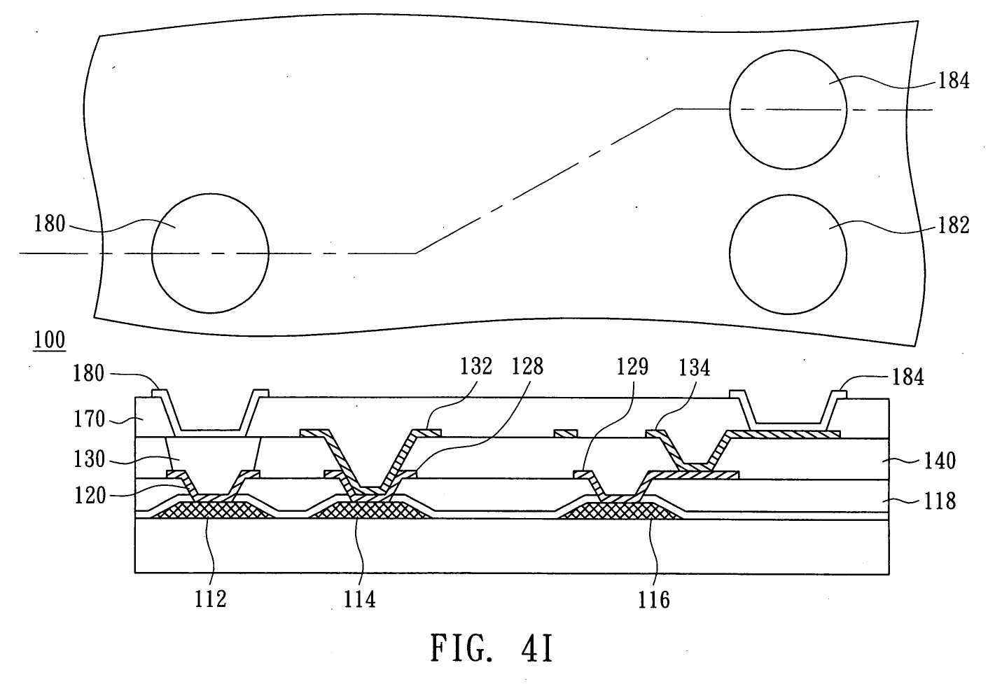

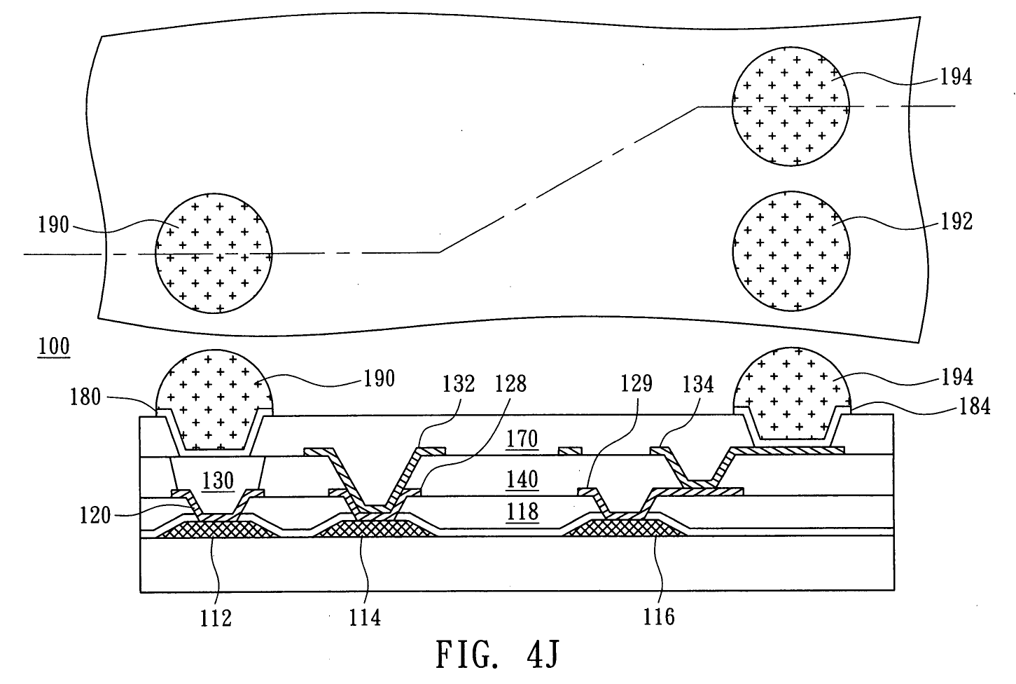

Referring to FIGS. 4A˜4J, several flowcharts of a method of fabricating a wafer structure according to the preferred embodiment of the invention are shown. Each flowchart includes an upper view and a cross-sectional view viewed along the cross-sectional line of the upper view. The steps of the method for fabricating the wafer structure of the present embodiment of the invention are disclosed below.

Firstly, as shown in FIG. 4A, a substrate 110 having several solder pads 112, 114, and 116 and a first passivation layer 118 is provided, wherein the first passivation layer 118 has a first aperture 118a to expose the solder pads 112, 114, and 116. Furthermore, for the bump of the solder pad 112 to be formed at the original position, the redistribution layer of the solder pad 114 must crisscross with the redistribution layer of the solder pad 116. Therefore, the redistribution structures of the solder pads 112, 114, and 116 are different from one another.

Next, a redistribution layer and a metallic pillar are formed. The preferable way of forming the metallic layer includes the following steps. Referring to FIG. 4B, a metallic layer 122 is formed on the first passivation layer 118 and the first aperture 118a. The metallic layer 122 disposed in the first aperture 118a forms an indented portion 122a. The way of forming the metallic layer 122 includes electroless plating, sputtering or chemical deposition. Afterwards, a photo-resist layer 124 is formed on the metallic layer 122. The photo-resist layer 124 is patterned to form a slot 124a to expose the indented portion 122a. Examples of the photo-resist layer 124 include a photo-resist solution or a dry film. Then, the metallic pillar 130 formed in the slot 124a by electroplating fills the indented portion 122a and is protruded from the metallic layer 122. Preferably, the metallic pillar 130 is a copper pillar. Next, the photo-resist layer 124 is removed as shown in FIG. 4C. Afterwards, another patterned photo-resist layer 126 is formed on the metallic layer 122 as shown in FIG. 4D. Lastly, the metallic layer 122 is patterned according to the metallic pillar 130 and another patterned photo-resist layer 126 to form several redistribution structures 120, 128 and 129 as shown in FIG. 4E. Referring to FIG. 4E, the redistribution layer 120 disposed in the first aperture 118a forms an indented portion 120a and covers the first passivation layer 118 forms a top portion 120b. To elaborate the above disclosure in greater details, the top portion 120b of the redistribution layer 120 of the bump predetermined to be formed at the original position is positioned at the original position, while the top portion 129a of the redistribution structure 129 of the bump predetermined to be formed elsewhere extends a distance towards the predetermined position of the bump on the first passivation layer 118. Particularly, the top portion 128a of the redistribution structure 128 of the bump predetermined to be formed elsewhere is also disposed at the original position so as to crisscross with the redistribution structure 129.

On the other hand, the redistribution layer and the metallic pillar can be separately formed. For example, the redistribution layer is first formed on the first passivation layer and the first aperture to form the indented portion of the redistribution layer, and then the metallic pillar is formed to fill the indented portion and is protruded from the redistribution layer. The formation of the redistribution layer includes the following steps: firstly, a metallic layer is formed on the first passivation layer and the first aperture; next, the metallic layer is patterned to form a redistribution layer; the redistribution layer disposed in the first aperture forms the indented portion and covers the first passivation layer to form the top portion. Moreover, the formation of the metallic pillar includes the following steps: a photo-resist layer is formed on the first passivation layer and the redistribution layer; the photo-resist layer is patterned to form a first aperture to expose the indented portion; and a metallic pillar is formed in the first aperture by electroplating, so that the metallic pillar fills the indented portion and is protruded from the redistribution layer.

Then, a second passivation layer 140 is formed on the first passivation layer 118 and surrounds the metallic pillar 130 as shown in FIG. 4F. The formation of the second passivation layer 140 includes rotary coating, chemical deposition, printing, draping, spraying and other methods. Preferably, the top surface of the second passivation layer 140 is disposed at the same height with the top surface of the metallic pillar 130. Besides, several apertures 140a are formed on the second passivation layer 140 to expose the redistribution layers 128 and 129. Afterwards, the second redistribution layers 132 and 134 are formed according to the above method of formation as shown in FIG. 4G. Furthermore, the top portion 132b of the redistribution layer 132 electrically connected to the solder pad 114 extends a distance on the second passivation layer 140, while the top portion 134b of the redistribution layer 134 electrically connected to the solder pad 116 extends a distance towards another direction on the second passivation layer 140 so as to crisscross with the redistribution layer 132. Thus, the redistribution structure is completed.

Afterwards, a third passivation layer 170 is formed on the second passivation layer 140. The third passivation layer 170 has a third aperture 170a to expose the metallic pillar 130 as shown in FIG. 4H. The way of forming the third passivation layer 170 includes rotary coating, chemical deposition, printing, draping, spraying and other methods. Meanwhile, the third aperture 170a of the third passivation layer also exposes the second redistribution layers 132 and 134 of the redistribution structure. Preferably, all of the first passivation layer, the second passivation layer and the third passivation layer include polyimide (Pl).

Next, several UBM layers 180, 182, 184 are formed in the third aperture 170a and on part of the third passivation layer 170 as shown in FIG. 41. The UBM layer is normally composed of an adhesion layer, a diffusion barrier layer and a wetting layer. The adhesion layer for providing adhesion between the solder pad and the passivation layer includes aluminum, titanium, chromium, tungsten-titanium alloy and other metals. The diffusion barrier layer for preventing metal diffusion between the bump and the solder pad includes nickel-vanadium alloy, nickel and other metals. The wetting layer for providing draping between the under bump metallurgy layer and the bump includes copper, molybdenum, platinum and other metals. Besides, the UBM layer 180 is electrically connected to the metallic pillar 130 with respect to the indented portion 120a. Thus, the bottom of the UBM layer 180 formed on the metallic pillar 130 is approximately disposed at the same height with the bottom of the UBM layer 184 formed on the second passivation layer 140. The cavity volume of the indented portion of the UBM layer 180 formed on the metallic pillar 130 is approximately the same with the cavity volume of the indented portion of the UBM layer 184 formed on the second passivation layer 140.

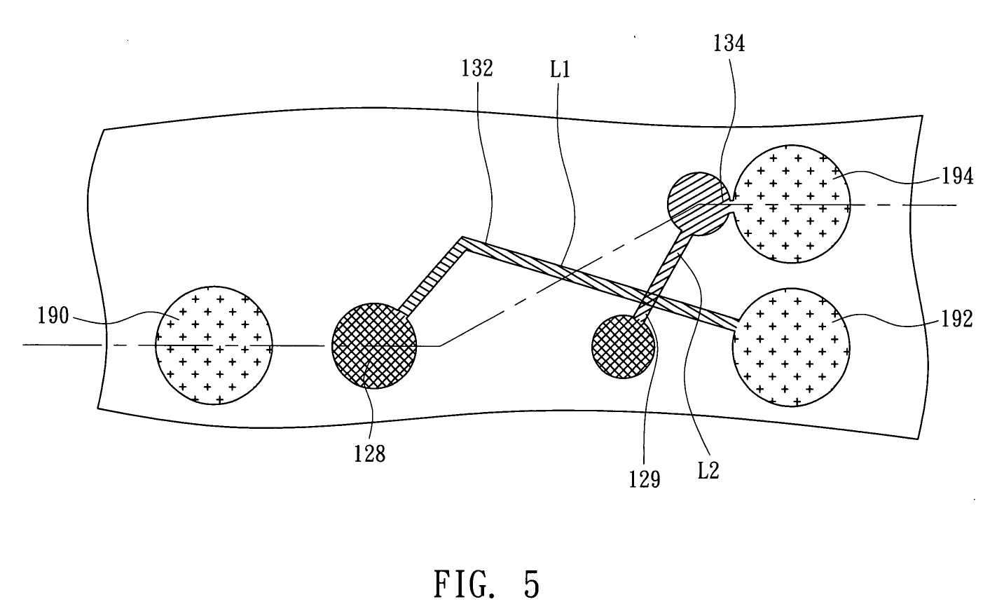

Lastly, the slot formed by patterning the photo-resist is filled with solder paste or electroplating solder and is disposed on the UBM layers 180, 182 and 184, and then the bumps 190, 192, and 194 are formed via the process of reflowing as shown in FIG. 4J; meanwhile, the patterned photo-resist is removed to complete the wafer structure 100 of the present embodiment of the invention. It is noted that the bumps 190, 192, and 194 are substantially of the same height and are without vertical height drop. Since the cavity volume of the indented portion of the UBM layer 180 is approximately the same with the cavity volume of the indented portion of the UBM layer 184, the amount of the solder paste or the electroplating solder used the indented portion of the UBM layer 180 is approximately the same with amount of the solder paste or the electroplating solder used to fill up the indented portion of the UBM layer 184. Consequently, the bumps formed according to the process of reflowing substantially have the same size and the same height. Referring to FIG. 5, a perspective of the redistribution structure of the wafer structure according to FIG. 4J is shown. In the wafer structure 100 of the present embodiment of the invention, the layout path L1 and the layout path L2 are crisscrossed but not short-circuited, because the redistribution layer 129 and the second redistribution layer 132 are disposed on different layers.

Despite the method of fabricating redistribution structure disclosed above is exemplified by three layers of the passivation layers 118, 140, and 170 and two layers of the redistribution layers, the invention is not limited thereto. The redistribution structure of the invention can be formed by alternately stacking N layers of the redistribution layers and (N−1) layers of the passivation layers, and a metallic pillar is added to the (N−1)^{th} passivation layer to fill the indented portion of the redistribution structure, so that the top portion of the metallic pillar has the same height with the top portion of the (N−1)^{th} passivation layer. Therefore, various redistribution structures are disposed at the same horizontal height before the UBM layer is formed. The UBM layers and the bumps are subsequently formed using the same material, having the same specifications and following the same manufacturing process, therefore the bumps have the same height.

According to the wafer structure and the method for fabricating the same disclosed in above embodiment of the invention, the bumps formed after redistribution have the same height. In the wafer structure of the invention, a metallic pillar is added to the redistribution structure to fill the indented portion formed in the redistribution structure extended from the original position of the solder pad. Therefore, the UBM layers and the bumps subsequently formed using the same material, having the same specifications and following the same manufacturing process would have the bumps of the same height. Besides, the contact between the redistribution layer and the metallic pillar as well as the contact between the metallic pillar and the UBM layer are excellent, avoiding the problem of detachment.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A wafer structure, comprising:
a substrate having a solder pad and a first passivation layer, wherein the first passivation layer has a first aperture to expose the solder pad;
a redistribution structure formed on the substrate, comprising:
at least one redistribution layer electrically connected to the solder pad, wherein the redistribution layer has at least one top portion and an indented portion;
a metallic pillar for filling the indented portion, wherein the metallic pillar is protruded from the top portion; and
a second passivation layer formed on the first passivation layer, wherein the second passivation layer surrounds the metallic pillar;
a third passivation layer formed on the redistribution structure, wherein the third passivation layer has a third aperture to expose the metallic pillar;
an under bump metallurgy (UBM) layer formed in the third aperture and disposed on the metallic pillar with respect to the indented portion; and
a bump formed on the UBM layer.

2. The wafer structure according to claim 1, wherein the metallic pillar is a copper pillar.

3. The wafer structure according to claim 1, wherein the top surface of the second passivation layer is disposed at the same height with the top surface of the metallic pillar.

4. The wafer structure according to claim 1, wherein the redistribution layer is formed in the first aperture and on the first passivation layer, the top portion covers the first passivation layer, and the indented portion is disposed in the first aperture.

5. A wafer structure, comprising:
a substrate having a solder pad;
a redistribution structure formed on the substrate, wherein the redistribution structure comprises at least one copper pillar electrically connected to the solder pad;
a passivation layer formed on the redistribution structure, wherein the passivation layer has an aperture to expose the copper pillar;
an under bump metallurgy (UBM) layer formed in the aperture and disposed on the copper pillar; and
a bump formed on the UBM layer.

6. The wafer structure according to claim 5, wherein the redistribution structure further comprises:
at least one redistribution layer electrically connected to the solder pad, wherein the redistribution structure has at least one top portion and an indented portion;
wherein the copper pillar fills the indented portion and is protruded from the top portion.

7. The wafer structure according to claim 6, further comprising a first passivation layer having a first aperture to expose the solder pad;
wherein the redistribution layer is formed in the first aperture and on the first passivation layer, and the top portion covers the first passivation layer, and the indented portion is disposed in the first aperture.

8. The wafer structure according to claim 7, further comprising a second passivation layer formed on the first passivation layer, wherein the second passivation layer surrounds the copper pillar, and the top surface of the second passivation layer is disposed at the same height with the top surface of the copper pillar.

9. A method for fabricating a wafer structure, comprising:
providing a substrate having a solder pad and a first passivation layer, wherein the first passivation layer has a first aperture to expose the solder pad;
forming a redistribution layer on the first passivation layer and in the first aperture, wherein the redistribution structure has an indented portion;
forming a metallic pillar to fill the indented portion, wherein the metallic pillar is protruded from the redistribution layer;
forming a second passivation layer on the first passivation layer, wherein the second passivation layer surrounds the metallic pillar;
forming a third passivation layer on the second passivation layer, wherein the third passivation layer has a third aperture to expose the metallic pillar;
forming an under bump metallurgy (UBM) layer in the third aperture and on part of the third passivation layer, wherein the UBM layer is electrically connected to the metallic pillar with respect to the indented portion; and
forming a bump on the UBM layer.

10. The method according to claim 9, wherein the step of forming the redistribution layer on the substrate comprises:
forming a metallic layer on the first passivation layer and in the first aperture; and
patterning the metallic layer to form the redistribution layer;
wherein the redistribution layer is disposed in the first aperture to form the indented portion and covers the first passivation layer to form a top portion.

11. The method according to claim 9, wherein the step of forming the metallic pillar comprises:
forming a photo-resist layer on the first passivation layer and the redistribution layer;
patterning the photo-resist layer to form a slot to expose the indented portion; and
forming the metallic pillar in the slot by electroplating, wherein the metallic pillar fills the indented portion and is protruded from the redistribution layer.

12. The method according to claim 9, wherein the redistribution layer is formed by etching the metallic pillar.

13. The method according to claim 9, wherein the metallic pillar is a copper pillar.

14. The method according to claim 9, wherein the top surface of the second passivation layer is disposed at the same height with the top surface of the metallic pillar.

15. The method according to claim 9, wherein the first passivation layer, the second passivation layer and the third passivation layer include polyimide (Pl).

16. The method according to claim 9, wherein the step of forming the redistribution layer and the step of forming the metallic pillar comprise:
forming a metallic layer on the first passivation layer and in the first aperture, wherein the metallic layer disposed in the first aperture forms the indented portion;
forming a photo-resist layer on the metallic layer;
patterning the photo-resist layer to form a slot to expose the indented portion; and
forming the metallic pillar in the slot by electroplating, wherein the metallic pillar fills the indented portion and is protruded from the metallic layer;
removing the photo-resist layer; and
patterning the metallic layer according to the metallic pillar to form the redistribution layer;
wherein the redistribution layer disposed in the first aperture forms the indented portion and covers the first passivation layer to form a top portion.
